(19) United States
(12) Patent Application Publication
(10) Pub. No.: US 2026/0024595 A1
(43) Pub. Date: Jan. 22, 2026

(54) DIFFERENTIATING READ DISTURB FROM RETENTION CHARGE LOSS

(71) Applicant: Micron Technology, Inc., Boise, ID (US)

(72) Inventors: Dongxiang Liao, Cupertino, CA (US); Daniel Zhang, Milpitas, CA (US)

(21) Appl. No.: 19/259,825

(22) Filed: Jul. 3, 2025

Related U.S. Application Data
(60) Provisional application No. 63/672,016, filed on Jul. 16, 2024.

(51) Int. Cl. G11C 16/34; G11C 16/08; G11C 16/26

(52) U.S. Cl. CPC G11C 16/3431; G11C 16/08; G11C 16/26

(57) ABSTRACT

Systems and methods for providing a memory sub-system controller selectively refresh data by differentiating between read disturb charge loss from data retention charge loss. The controller performs a read disturb induced charge loss (RDCL) scan operation on a portion of a set of memory components. The controller determines that a first bit error count (BEC) associated with the RDCL scan operation on the portion of the set of memory components transgresses a threshold value and determines whether the first BEC corresponds to a second BEC that represents data retention (DR) charge loss. The controller selectively refreshes data stored in the portion of the set of memory components based on determining whether the first BEC corresponds to the second BEC that represents DR charge loss.

### PRIORITY APPLICATION

This application claims the benefit of priority to U.S. Provisional Application Ser. No. 63/672,016, filed Jul. 16, 2024, which is incorporated herein by reference in its entirety.

### TECHNICAL FIELD

This disclosure relates generally to memory sub-systems and, more specifically, to providing adaptive media management for memory components, such as memory dies.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 is a block diagram illustrating an example computing environment including a memory sub-system, in accordance with some examples.

FIG. 2 is a block diagram of an example media operations manager, in accordance with some examples.

FIGS. 3 and 4 are block diagrams of examples of read disturb induced charge loss (RDCL) scan operations, in accordance with some examples.

FIG. 5 is a flow diagram of an example method to selectively refresh data stored in the memory components, in accordance with some examples.

FIG. 6 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

The present disclosure configures a system component, such as a memory sub-system controller, to selectively refresh data stored in a portion of the memory components (e.g., word line (WL), WL group (WLG), memory block, memory page, memory die, and/or sub-block) based on a determination of whether a bit error count (BEC) results from RDCL or data retention (DR) charge loss. The memory sub-system controller can perform an RDCL scan operation on the portion of the memory components. If a read bit error rate (RBER) resulting from the RDCL scan operation transgresses a threshold, the controller can selectively refresh the data based on a determination of whether the RBER results from RDCL or DR charge loss. Namely, if the RBER is determined to be the result of RDCL, the controller can immediately refresh the data stored in the portion. If the RBER is determined to be the result of DR charge loss, the controller can delay or prevent refreshing the data until another time when the DR charge loss reaches a certain threshold. This ensures that performance of the memory system remains optimal, such as by refraining from unnecessarily refreshing data stored in the memory components. This improves the overall efficiency of operating the memory sub-system.

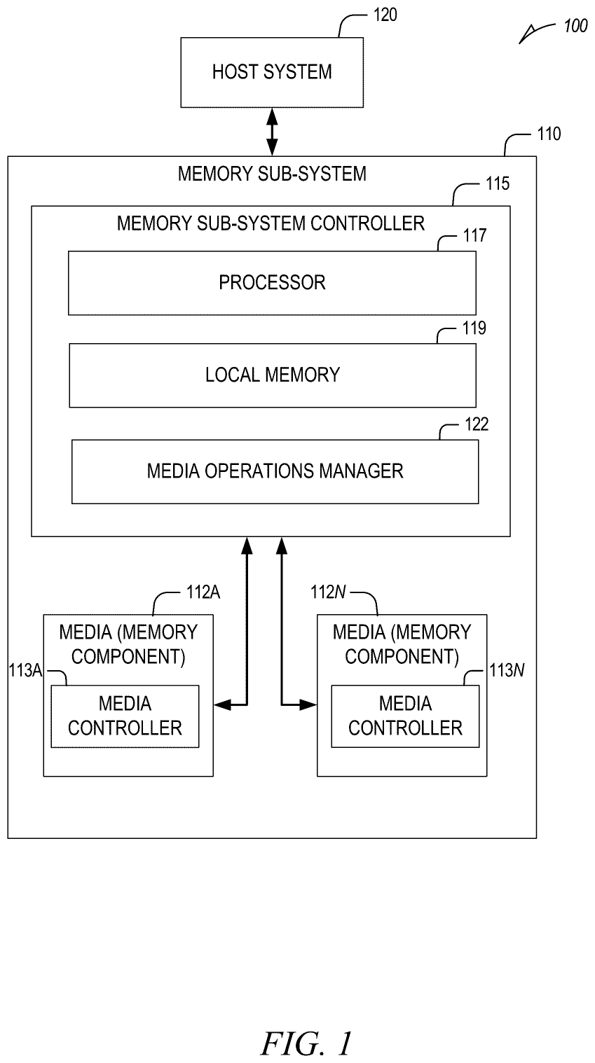

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as “garbage collection data.” “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

There are challenges in efficiently managing or performing media management operations on typical memory devices. Specifically, certain memory devices, such as NAND flash devices, include large die-by-die reliability (RWB) variation. As the technology for such memory devices continues to be scaled down, this die-by-die reliability variation becomes more pronounced and problematic in performing memory management. Current memory systems (e.g., SSD drive or die package systems) associate all of the memory devices or memory dies in the memory system with a certain reliability specification. Such reliability specifications can be set based on a RBER of different portions of the memory sub-system. In some cases, each block of each memory device is associated with a reliability grade or specification which is used to determine whether the block is a good block or a bad block. Good blocks are those that have reliability grades (e.g., RBER values) above a reliability threshold (e.g., above an RBER threshold) and bad blocks are blocks that have reliability grades below a reliability threshold. The reliability grades can be set at manufacture or during operation of the memory devices, such as by measuring the data retention and/or error rate associated with particular blocks, WLs, WLGs, and/or sub-blocks (SBs).

Some media management operations include RDCL scan operations. The RDCL scan operations in NAND flash memory is an important maintenance process aimed at preserving data integrity. The RDCL operations begin with the memory controller monitoring the number of read operations for each memory block, WL, WLG, or other suitable portion. Once the portion reaches a predefined threshold of read operations, indicating a higher risk of data corruption due to read disturbs, the portion is flagged for further action. The memory controller then checks the charge levels in the cells of these portions to detect any discrepancies or charge loss. If issues are found, the original data is rewritten to the cells, restoring the correct charge levels and correcting errors (e.g., the data is refreshed). In some cases, the RDCL operations are performed on certain predetermined or mandatory WLs or portions.

In the realm of NAND flash memory management, distinguishing between different types of charge loss—specifically RDCL and DR charge loss (RDCL)—is important for optimizing the efficiency and longevity of memory devices. The inability of a memory controller to differentiate between these two types of charge loss leads to significant inefficiencies and waste of resources, impacting overall system performance and durability. RDCL occurs when the charge state of a NAND cell is altered due to the electrical interference from read operations on neighboring cells. This type of charge loss is typically immediate and localized, necessitating prompt corrective actions to prevent data corruption. Memory controllers are programmed to respond to RDCL by performing immediate refresh operations on the affected blocks, restoring data integrity swiftly. On the other hand, RDCL results from the natural degradation of charge in the NAND cells over time, irrespective of read operations. RDCL is a gradual process, influenced by factors such as the age of the memory and environmental conditions. Unlike RDCL, the effects of RDCL do not necessitate immediate correction, as the data remains stable over a relatively longer period before refresh operations are required. RDCL is usually dealt with by refreshing blocks of data when the read window budget (RWB) reduction starts to post a threat to reliability.

The inefficiency arises when memory controllers treat all instances of charge loss as if they were caused by RDCL, leading to unnecessary and premature refresh operations. This not only wastes computational resources and power but also contributes to increased wear and tear on the memory cells, thereby reducing the overall lifespan of the memory device. Each unnecessary refresh cycle accelerates the wear of the NAND cells, pushing the memory closer to its end-of-life prematurely. Moreover, this lack of distinction between RDCL and RDCL can lead to suboptimal data management practices. For instance, immediate refreshes increase the operational overhead and can cause performance bottlenecks, especially in high-demand environments where system speed and efficiency are critical. Additionally, the increased power consumption required for these unnecessary refreshes contributes to higher operational costs and environmental impact. Some memory systems maintain read counters for various portions of the memory to help distinguish these types of charge losses. However, these read counters come at a cost of overhead and storage space which wastes resources and reduces the efficiency of the memory sub-system.

The present disclosure addresses the above and other deficiencies by providing a memory controller that can selectively and intelligently perform refresh operations by distinguishing between RDCL and RDCL for data stored on portions of the memory components (e.g., certain WL, WLGs, memory blocks, memory dies, and so forth). This is performed without adding overhead, such as read counters, which improves the overall efficiency of operating the memory sub-system. Specifically, the memory sub-system controller can perform an RDCL scan operation on the portion of the memory components. If a RBER resulting from the RDCL scan operation transgresses a threshold, the controller can selectively refresh the data based on a determination of whether the RBER results from RDCL or DR charge loss. Namely, if the RBER is determined to be the result of RDCL, the controller can immediately refresh the data stored in the portion. If the RBER is determined to be the result of DR charge loss, the controller can delay or prevent refreshing the data until another time when the DR charge loss reaches a certain threshold. This ensures that performance of the memory system remains optimal, such as by refraining from unnecessarily refreshing data stored in the memory components. This improves the overall efficiency of operating the memory sub-system.

In some examples, the controller performs a RDCL scan operation on a portion of the set of memory components and determines that a first bit error count (BEC) associated with the RDCL scan operation on the portion of the set of memory components transgresses a threshold value. In such cases, the controller determines whether the first BEC corresponds to a second BEC that represents DR charge loss. The controller can selectively refresh data stored in the portion of the set of memory components based on determining whether the first BEC corresponds to the second BEC that represents DR charge loss. The memory sub-system can include a three-dimensional (3D) NAND memory.

The controller can measure a RBER value resulting from reading the portion of the set of memory components in response to performing the RDCL scan operation to compute the first BEC. The controller can obtain the second BEC from a look-up table including a block family error avoidance (BFEA) bin corresponding to the portion of the set of memory components. In some cases, the second BEC can be obtained from the look-up table in response to determining that the RDCL scan operation is performed on tri-level cell (TLC) storage. The controller can identify a predetermined portion of the set of memory components that is unlikely to be impacted by RDCL and reads data stored in the predetermined portion of the set of memory components. The controller can compute the second BEC in response to reading the data stored in the predetermined portion of the set of memory components.

In some examples, the predetermined portion of the set of memory components includes a reference WL used to represent known DR charge loss. The RDCL scan operation can be performed on TLC storage. The RDCL scan operation can be performed on quad-level cell (QLC) storage.

The controller can compute a difference between the first BEC and the second BEC and compare the difference to a refresh threshold value. In some cases, the controller determines that the difference transgresses the refresh threshold value. The controller, in response to determining that the difference transgresses the refresh threshold value, causes data stored in the portion of the set of memory components to be refreshed. In some examples, the controller refreshes the data based on a reliability value of the portion of the set of memory components representing tolerance of the portion to additional RDCL.

The controller can determine that the difference fails to transgress the refresh threshold value and, in response to determining that the difference fails to transgress the refresh threshold value, delays refreshing of the data stored in the portion of the set of memory components. In some cases, the BECs resulting from RDCL causes data to be refreshed in the portion of the set of memory components earlier than BECs resulting from DR charge loss. In some cases, the portion includes at least one of a set of WLs, WLGs, or a set of memory dies. The RDCL scan operation can be triggered periodically. The RDCL scan operation can be triggered in response to determining that a number of read operations performed on the memory sub-system within a predetermined interval transgresses a threshold value.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing environment 100 including a memory sub-system 110, in accordance with some examples. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies). Each memory die can include a plurality of planes in which data can be stored or programmed.

In some examples, the first memory component 112A including one or more portions (e.g., one or more WLs, one or more WLGs, one or more blocks, one or more memory dies, and/or one or more pages), or group of memory components including the first memory component 112A can be associated with a first reliability (capability) grade, value, measure, or lifetime PEC. The terms “reliability grade,” “value” and “measure” are used interchangeably throughout and can have the same meaning. The second memory component 112N (e.g., one or more WLs, one or more WLGs, one or more blocks, one or more memory dies, and/or one or more pages) or group of memory components including the second memory component 112N can be associated with a second reliability (capability) grade, value, measure, or lifetime PEC. In some examples, each memory component 112A to 112N can store respective configuration data that specifies the respective reliability grade and lifetime PEC and current PEC. In some examples, a memory or register can be associated with all of the memory components 112A to 112N and can store a table that maps different groups, portions, bins or sets of the memory components 112A to 112N to respective reliability grades, lifetime PEC values, and/or current PEC values.

In some examples, a memory or register can be associated with all the memory components 112A to 112N and can store a table or map that maps different WL, WLGs, SBs, memory dies, and/or portions of the memory components 112A to 112N to reliability values that transgress a threshold. Namely, the memory or register can store a map that lists each WL, WLG, and/or SB that has been determined during manufacture to be defective (e.g., have a reliability value that fails to transgress a reliability threshold). In some cases, the table or map can be generated based on a distribution of errors or defects associated with a certain wafer, die sort, lot, or batch. A determination can be made that the memory sub-system 110 is part of a particular wafer, die sort, lot or batch and can then be loaded with the configuration data that includes the table or map associated with another memory sub-system 110 that is part of the same wafer, die sort, lot, or batch. In some cases, the list of portions that are in the table are referred to as mandatory WLs or mandatory portions (e.g., predetermined portions of the set of memory components 112A to 112N). These mandatory portions can be included in an RDCL scan operation to condition performing refresh operations if the RBER of the data read from the portions transgresses a maximum or predefined RBER threshold.

In some cases, the memory or register can store a table or map that specifies reference portions or WLs or WLGs that are unlikely to be impacted by RDCL. These portions can be used by the memory sub-system controller 115 to selectively refresh data stored in portions of the set of memory components 112A to 112N in response to performing an RDCL scan operation that includes a BEC or RBER that transgresses a threshold, as discussed below. The memory or register can also or alternatively store a BFEA table that associates different bins of the set of memory components 112A to 112N with known or corresponding RBER or BEC, such as the RBER or BEC associated with DR charge loss.

In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some examples, the host system 120 is coupled to different types of memory sub-systems 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components. An example of non-volatile memory components includes a negative-and (NAND)-type flash memory and/or a 3D NAND flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory. In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative or (NOR) flash memory, electrically erasable programmable read-only memory (EEPROM), and a cross-point array of non-volatile memory cells.

A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. For example, a single first row that spans a first set of the pages or blocks of the memory components 112A to 112N can correspond to or be grouped as a first block stripe and a single second row that spans a second set of the pages or blocks of the memory components 112A to 112N can correspond to or be grouped as a second block stripe.

The memory sub-system controller 115 can communicate with the memory components 112A to 112N to perform memory operations such as reading data, writing data, or erasing data at the memory components 112A to 112N and other such operations. The memory sub-system controller 115 can communicate with the memory components 112A to 112N to perform various memory management operations, such as different scan rates, different scan frequencies, different wear leveling, different read disturb management, garbage collection operations, different near miss ECC operations, RDCL scan operations, and/or different dynamic data refresh.

The memory sub-system controller 115 can include hardware such as one or more integrated circuits and/or discrete components, a buffer memory, or a combination thereof. The memory sub-system controller 115 can be a microcontroller, special-purpose logic circuitry (e.g., a field programmable gate array (FPGA), an application specific integrated circuit (ASIC, etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some embodiments, the local memory 119 can include memory registers storing memory pointers, fetched data, and so forth. The local memory 119 can also include read-only memory (ROM) for storing microcode. While the example memory sub-system 110 in FIG. 1 has been illustrated as including the memory sub-system controller 115, in another example of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112N to 112N. The configuration data can describe the lifetime PEC values and/or reliability grades associated with different groups of the memory components 112N to 112N and/or different WLs, WLGs, and/or blocks within each of the memory components 112N to 112N. The configuration data can include a table that lists WLs, WLGs, and/or SBs that are known to be defective to be included as part of the mandatory WLs, WLGs, and/or SBs to include in an RDCL scan. The configuration data can specify reference portions or WLs or WLGs that are unlikely to be impacted by RDCL. These portions can be used by the memory sub-system controller 115 to selectively refresh data stored in portions of the set of memory components 112A to 112N in response to performing an RDCL scan operation that includes a BEC or RBER that transgresses a threshold. The configuration data can also or alternatively store a BFEA table that associates different bins of the set of memory components 112A to 112N with known or corresponding RBER or BEC, such as the RBER or BEC associated with DR charge loss.

The memory sub-system controller 115 can be responsible for other memory management operations, such as wear leveling operations, garbage collection operations, error detection and error-correcting code (ECC) operations, encryption operations, caching operations, read scan, and address translations. The memory sub-system controller 115 can further include host interface circuitry to communicate with the host system 120 via the physical host interface. The host interface circuitry can convert the commands received from the host system 120 into command instructions to access the memory components 112A to 112N as well as convert responses associated with the memory components 112A to 112N into information for the host system 120.

The memory sub-system 110 can also include additional circuitry or components that are not illustrated. In some embodiments, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory device can be a managed memory device (e.g., managed NAND), which is a raw memory device combined with a local embedded controller (e.g., local media controllers) for memory management within the same memory device package. Any one of the memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

The memory sub-system controller 115 can include a media operations manager 122. The media operations manager 122 can selectively refresh data stored in a portion of the memory components (e.g., WL, WLG, memory block, memory page, memory die, and/or sub-block) based on a determination of whether a BEC results from RDCL or DR charge loss. The media operations manager 122 can perform an RDCL scan operation on the portion of the memory components. If a RBER resulting from the RDCL scan operation transgresses a threshold, the media operations manager 122 can selectively refresh the data based on a determination of whether the RBER results from RDCL or DR charge loss. Namely, if the RBER is determined to be the result of RDCL, the media operations manager 122 can immediately refresh the data stored in the portion. If the RBER is determined to be the result of DR charge loss, the media operations manager 122 can delay or prevent refreshing the data until another time when the DR charge loss reaches a certain threshold. This ensures that performance of the memory sub-system 110 remains optimal, such as by refraining from unnecessarily refreshing data stored in the memory components. This improves the overall efficiency of operating the memory sub-system 110.

In some examples, the media operations manager 122 can comprise logic (e.g., a set of transitory or non-transitory machine instructions, such as firmware) or one or more components that causes the media operations manager 122 to perform operations described herein. The media operations manager 122 can comprise a tangible or non-tangible unit capable of performing operations described herein. Further details with regards to the operations of the media operations manager 122 are described below.

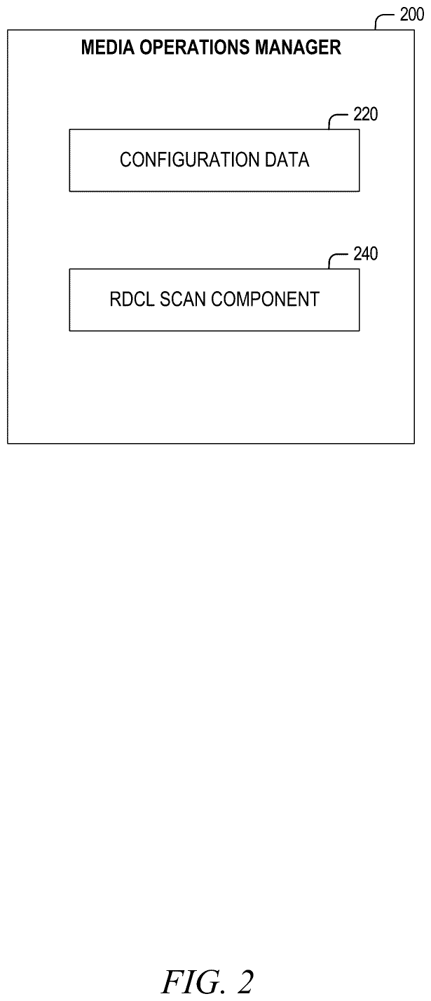

FIG. 2 is a block diagram of an example media operations manager 200 (corresponding to media operations manager 122 of FIG. 1), in accordance with some examples. As illustrated, the media operations manager 200 includes configuration data 220 and a RDCL scan component 240. For some cases, the media operations manager 200 can differ in components or arrangement (e.g., less or more components) from what is illustrated in FIG. 2.

The configuration data 220 (e.g., configuration data component) accesses and/or stores configuration data associated with the memory components 112A to 112N of FIG. 1. In some examples, the configuration data 220 is programmed into the media operations manager 200. For example, the media operations manager 200 can communicate with the memory components 112A to 112N to obtain the configuration data and store the configuration data 220 locally on the media operations manager 122. In some examples, the media operations manager 122 communicates with the host system 120. The host system 120 receives input from an operator or user that specifies parameters including the list (or map) of different WLs, WLGs, bins, groups, blocks, block stripes, memory dies and/or sets of the memory components 112A to 112N that are defective (e.g., have a reliability value that fails to transgress a reliability threshold). The list or map can identify the mandatory portions to be included as part of an RDCL scan operation.

The list or map stored in the configuration data 220 can also specify reference portions or WLs or WLGs that are unlikely to be impacted by RDCL. These portions can be used by the media operations manager 200 to selectively refresh data stored in portions of the set of memory components 112A to 112N in response to performing an RDCL scan operation that includes a BEC or RBER that transgresses a threshold. The configuration data 220 can also or alternatively store a BFEA table that associates different bins of the set of memory components 112A to 112N with known or corresponding RBER or BEC, such as the RBER or BEC associated with DR charge loss.

The media operations manager 122 receives configuration data from the host system 120 of FIG. 1 and stores the configuration data in the configuration data 220. The configuration data 220 can store a table or map that identifies different WL, WLGs, and/or SBs of the memory components 112A to 112N that are defective.

In some cases, the configuration data 220 can store reliability criteria that can be used to control whether an individual portion of the set of memory components 112A to 112N is included in a list of defective portions or portions having a low reliability value. Specifically, the configuration data 220 can store a predetermined RBER threshold that controls whether a memory block associated with one or more WLs is refreshed as a result of the RDCL scan operations. In such cases, one or more portions (e.g., WLs or WLGs) which can be mandatory portions or subsets of the mandatory portions are scanned as part of the RDCL scan operations. An RBER value is computed or measured based on the result of performing the RDCL scan operation. In response to the RDCL scan component 240 determining that the RBER value associated with the one or more portions being scanned transgresses or exceeds the predetermined RBER threshold, the RDCL scan component 240 can refresh the data stored in the one or more portions that were scanned.

In some cases, rather than immediately refreshing the data, the RDCL scan component 240 can determine whether the RBER value or BEC resulting from the RDCL scan operation corresponds to DR charge loss. If so, the RDCL scan component 240 can refrain or delay performing the refresh operations until a criterion is satisfied for refreshing data having errors resulting from DR charge loss. To determine whether the RBER value or BEC resulting from the RDCL scan operation corresponds to DR charge loss, the RDCL scan component 240 can access the RBER or BEC associated with a known WL or portion of the set of memory components 112A to 112N that corresponds to or represents DR charge loss. For example, the RDCL scan component 240 can access the configuration data 220 to identify a reference portion or portions that represent DR charge loss BEC or RBER.

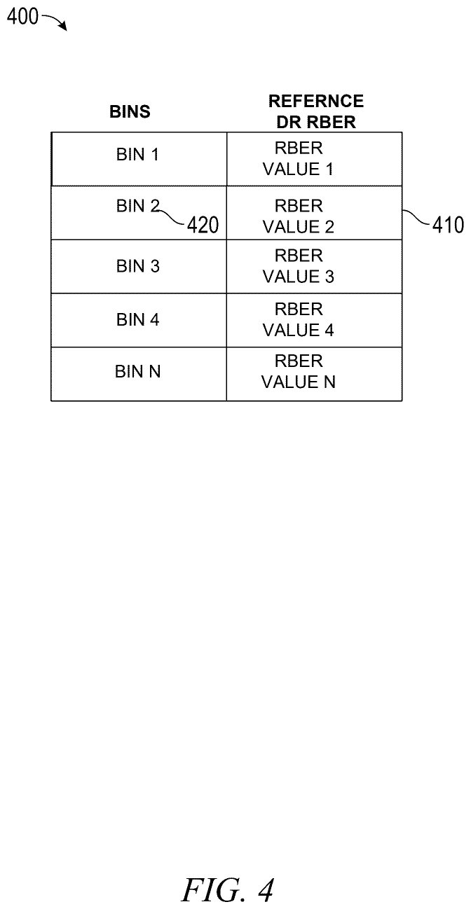

In some examples, such as if the RDCL scan operation is performed on TLC storage, the RDCL scan component 240 can access, from the configuration data 220, an RBER value stored in a BFEA bin. For example, the RDCL scan component 240 can determine a BFEA bin corresponding to the portion for which the RDCL scan operation was performed. The RDCL scan component 240 can then search the BFEA bin table 400, shown in FIG. 4, for the BFEA bin 420 corresponding to the determined BFEA bin. The RDCL scan component 240 retrieves from the BFEA bin table 400 the corresponding reference DR RBER 410 for the determined BFEA bin 420. The RDCL scan component 240 can compare the RBER or BEC resulting from performing the RDCL scan with the reference DR RBER retrieved from the BFEA bin table 400. The RDCL scan component 240 can compute a difference between the two RBER values. The RDCL scan component 240 can compare the difference to a threshold value.

If the difference transgresses the threshold value, the RDCL scan component 240 can determine that the RBER results from RDCL. In such cases, the RDCL scan component 240 can immediately (or upon satisfaction of one or more additional criteria, such as based on a reliability value of the portion of the set of memory components representing tolerance of the portion to additional RDCL) refresh the data stored in the block corresponding to the portion of the set of memory components 112A to 112N for which the RDCL scan operation was performed. If the RDCL scan component 240 determines that the difference fails to transgress the threshold value, the RDCL scan component 240 determines that the RBER results from DR charge loss. In such cases, the RDCL scan component 240 delays or prevents refreshing the data stored in the block corresponding to the portion of the set of memory components 112A to 112N for which the RDCL scan operation was performed until a criterion for refreshing DR charge loss errors is met.

In some examples, the RDCL scan operation is performed on QLC storage. In such cases (or also if the RDCL scan operation is performed on TLC storage), the RDCL scan component 240 can access, from the configuration data 220, one or more reference portions or WL that are unlikely to be impacted by RDCL.

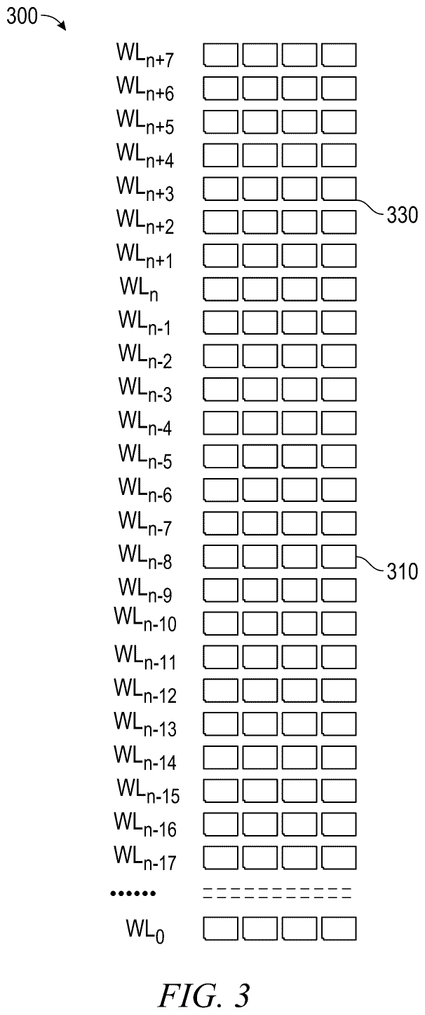

For example, as shown in the diagram 300 of FIG. 3, the RDCL scan component 240 of FIG. 2 can scan WL 310 (e.g., mandatory WLs). The RDCL scan component 240 can determine that the WL 310 is associated with a reliability value that fails to satisfy the reliability criterion in response to determining that the RBER of the data stored in the WL 310 transgresses an RBER threshold. In such cases, the RDCL scan component 240 can access the configuration data 220 to identify a reference WL 330 that represents DR charge loss RBER. The RDCL scan component 240 can read the data stored in a memory block associated with the reference WL 330. The RDCL scan component 240 can compute or measure the RBER resulting from reading the data stored in the memory block associated with the reference WL 330.

The RDCL scan component 240 can compare the RBER or BEC resulting from performing the RDCL scan with the RBER measured as a result of reading the data stored in the memory block associated with the reference WL 330. The RDCL scan component 240 can compute a difference between the two RBER values. The RDCL scan component 240 can compare the difference to a threshold value.

If the difference transgresses the threshold value, the RDCL scan component 240 can determine that the RBER results from RDCL. In such cases, the RDCL scan component 240 can immediately (or upon satisfaction of one or more additional criteria, such as based on a reliability value of the portion of the set of memory components representing tolerance of the portion to additional RDCL) refresh the data stored in the block corresponding to the portion of the set of memory components 112A to 112N for which the RDCL scan operation was performed. If the RDCL scan component 240 determines that the difference fails to transgress the threshold value, the RDCL scan component 240 determines that the RBER results from DR charge loss. In such cases, the RDCL scan component 240 delays or prevents refreshing the data stored in the block corresponding to the portion of the set of memory components 112A to 112N for which the RDCL scan operation was performed until a criterion for refreshing DR charge loss errors is met.

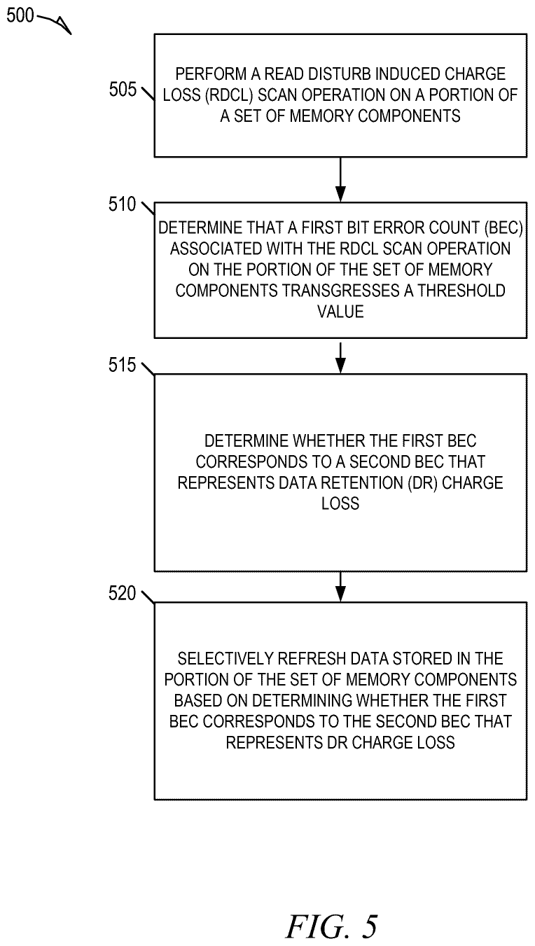

FIG. 5 is a flow diagram of an example method 500 (or process) to selectively refresh data stored in the memory components, in accordance with some examples. The method 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 500 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 5, the method (or process) 500 begins at operation 505, with a media operations manager 122 of FIG. 1 of a memory sub-system (e.g., memory sub-system 110 of FIG. 1) performing a RDCL scan operation on a portion of a set of memory components. Then, at operation 510, the media operations manager 122 of the memory sub-system determines that a first BEC associated with the RDCL scan operation on the portion of the set of memory components transgresses a threshold value and, at operation 515, determines whether the first BEC corresponds to a second BEC that represents DR charge loss. Thereafter, at operation 520, the media operations manager 122 selectively refreshes data stored in the portion of the set of memory components based on determining whether the first BEC corresponds to the second BEC that represents DR charge loss.

In view of the disclosure above, various examples are set forth below. It should be noted that one or more features of an example, taken in isolation or combination, should be considered within the disclosure of this application.

Example 1. A system comprising: a set of memory components of a memory sub-system; at least one processing device operatively coupled to the set of memory components, the at least one processing device being configured to perform operations comprising: performing a read disturb induced charge loss (RDCL) scan operation on a portion of the set of memory components; determining that a first bit error count (BEC) associated with the RDCL scan operation on the portion of the set of memory components transgresses a threshold value; determining whether the first BEC corresponds to a second BEC that represents data retention (DR) charge loss; and selectively refreshing data stored in the portion of the set of memory components based on determining whether the first BEC corresponds to the second BEC that represents DR charge loss.

Example 2. The system of Example 1, wherein the memory sub-system comprises a three-dimensional (3D) NAND memory.

Example 3. The system of any one of Examples 1-2, the operations comprising: measuring a read bit error rate (RBER) value resulting from reading the portion of the set of memory components in response to performing the RDCL scan operation to compute the first BEC.

Example 4. The system of any one of Examples 1-3, the operations comprising: obtaining the second BEC from a look-up table comprising a block family error avoidance (BFEA) bin corresponding to the portion of the set of memory components.

Example 5. The system of Example 4, wherein the second BEC is obtained from the look-up table in response to determining that the RDCL scan operation is performed on tri-level cell (TLC) storage.

Example 6. The system of any one of Examples 1-5, the operations comprising: identifying a predetermined portion of the set of memory components that is unlikely to be impacted by RDCL; reading data stored in the predetermined portion of the set of memory components; and computing the second BEC in response to reading the data stored in the predetermined portion of the set of memory components.

Example 7. The system of Example 6, wherein the predetermined portion of the set of memory components comprises a reference word line (WL) used to represent known DR charge loss.

Example 8. The system of Example 7, wherein the RDCL scan operation is performed on tri-level cell (TLC) storage.

Example 9. The system of any one of Examples 7-8, wherein the RDCL scan operation is performed on quad-level cell (QLC) storage.

Example 10. The system of any one of Examples 1-9, the operations comprising: computing a difference between the first BEC and the second BEC; and comparing the difference to a refresh threshold value.

Example 11. The system of Example 10, the operations comprising: determining that the difference transgresses the refresh threshold value; and in response to determining that the difference transgresses the refresh threshold value, causing data stored in the portion of the set of memory components to be refreshed.

Example 12. The system of Example 11, the operations comprising: refreshing the data based on a reliability value of the portion of the set of memory components representing tolerance of the portion to additional RDCL.

Example 13. The system of any one of Examples 10-12, the operations comprising: determining that the difference fails to transgress the refresh threshold value; and in response to determining that the difference fails to transgress the refresh threshold value, delaying refreshing of data stored in the portion of the set of memory components.

Example 14. The system of any one of Examples 1-13, wherein BECs resulting from RDCL cause data to be refreshed in the portion of the set of memory components earlier than BECs resulting from DR charge loss.

Example 15. The system of any one of Examples 1-14, wherein the portion comprises at least one of a set of word lines (WLs), WL groups (WLGs), or set of memory dies.

Example 16. The system of any one of Examples 1-15, wherein the RDCL scan operation is triggered periodically.

Example 17. The system of any one of Examples 1-16, wherein the RDCL scan operation is triggered in response to determining that a number of read operations performed on the memory sub-system within a predetermined interval transgresses a threshold value.

Methods and computer-readable storage medium with instructions for performing any one of the above examples.

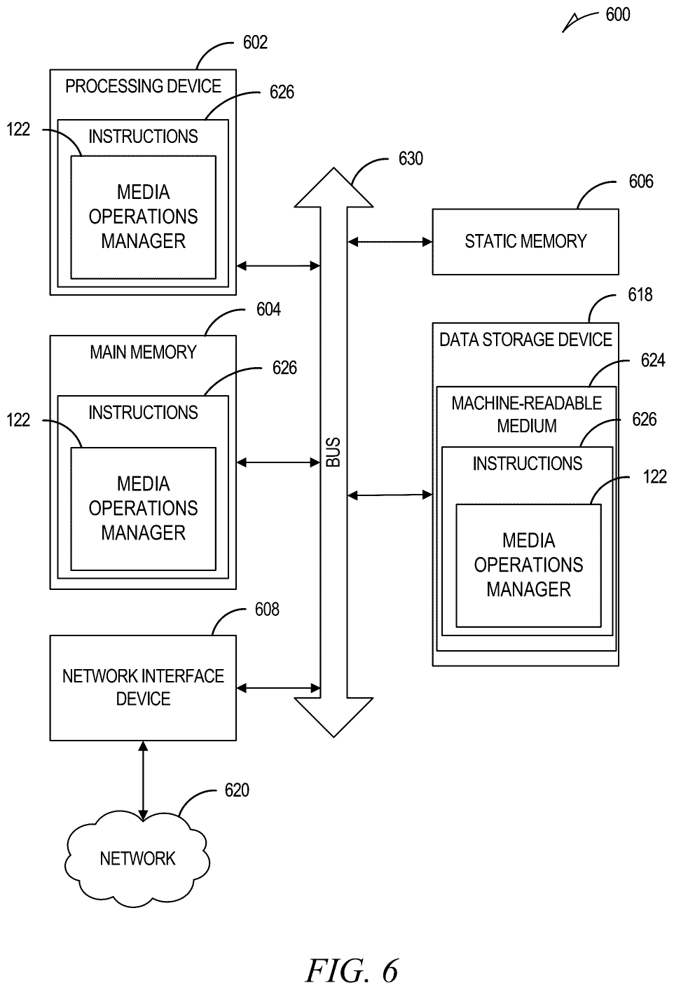

FIG. 6 illustrates an example machine in the form of a computer system 600 within which a set of instructions can be executed for causing the machine to perform any one or more of the methodologies discussed herein. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random-access memory (DRAM) such as synchronous DRAM (SDRAM) or Rambus DRAM (RDRAM), etc.), a static memory 606 (e.g., flash memory, static random access memory (SRAM), etc.), and a data storage device 618, which communicate with each other via a bus 630.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), a network processor, or the like. The processing device 602 is configured to execute instructions 626 for performing the operations and steps discussed herein. The computer system 600 can further include a network interface device 608 to communicate over a network 620.

The data storage device 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage device 618, and/or main memory 604 can correspond to the memory sub-system 110 of FIG. 1.

In one example, the instructions 626 implement functionality corresponding to the media operations manager 122 of FIG. 1. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; read-only memories (ROMs); random access memories (RAMs); erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine-readable (e.g., computer-readable) storage medium such as a read-only memory (ROM), random access memory (RAM), magnetic disk storage media, optical storage media, flash memory components, and so forth.

In the foregoing specification, various examples of the disclosure have been described. It will be evident that various modifications can be made thereto without departing from the broader scope of the disclosure as set forth in the following claims. The specification and drawings are, accordingly, to be regarded in an illustrative sense rather than a restrictive sense.

What is claimed is:

1. A system comprising:
a set of memory components of a memory sub-system;
at least one processing device operatively coupled to the set of memory components, the at least one processing device being configured to perform operations comprising:
performing a read disturb induced charge loss (RDCL) scan operation on a portion of the set of memory components;
determining that a first bit error count (BEC) associated with the RDCL scan operation on the portion of the set of memory components transgresses a threshold value;
determining whether the first BEC corresponds to a second BEC that represents data retention (DR) charge loss; and
selectively refreshing data stored in the portion of the set of memory components based on determining whether the first BEC corresponds to the second BEC that represents DR charge loss.

2. The system of claim 1, wherein the memory sub-system comprises a three-dimensional (3D) NAND memory.

3. The system of claim 1, the operations comprising:
measuring a read bit error rate (RBER) value resulting from reading the portion of the set of memory components in response to performing the RDCL scan operation to compute the first BEC.

4. The system of claim 1, the operations comprising:
obtaining the second BEC from a look-up table comprising a block family error avoidance (BFEA) bin corresponding to the portion of the set of memory components.

5. The system of claim 4, wherein the second BEC is obtained from the look-up table in response to determining that the RDCL scan operation is performed on tri-level cell (TLC) storage.

6. The system of claim 1, the operations comprising:
identifying a predetermined portion of the set of memory components that is unlikely to be impacted by RDCL;
reading data stored in the predetermined portion of the set of memory components; and
computing the second BEC in response to reading the data stored in the predetermined portion of the set of memory components.

7. The system of claim 6, wherein the predetermined portion of the set of memory components comprises a reference word line (WL) used to represent known DR charge loss.

8. The system of claim 7, wherein the RDCL scan operation is performed on tri-level cell (TLC) storage.

9. The system of claim 7, wherein the RDCL scan operation is performed on quad-level cell (QLC) storage.

10. The system of claim 1, the operations comprising:
computing a difference between the first BEC and the second BEC; and
comparing the difference to a refresh threshold value.

11. The system of claim 10, the operations comprising:
determining that the difference transgresses the refresh threshold value; and
in response to determining that the difference transgresses the refresh threshold value, causing data stored in the portion of the set of memory components to be refreshed.

12. The system of claim 11, the operations comprising:
refreshing the data based on a reliability value of the portion of the set of memory components representing tolerance of the portion to additional RDCL.

13. The system of claim 10, the operations comprising:
determining that the difference fails to transgress the refresh threshold value; and
in response to determining that the difference fails to transgress the refresh threshold value, delaying refreshing of data stored in the portion of the set of memory components.

14. The system of claim 1, wherein BECs resulting from RDCL cause data to be refreshed in the portion of the set of memory components earlier than BECs resulting from DR charge loss.

15. The system of claim 1, wherein the portion comprises at least one of a set of word lines (WLs), WL groups (WLGs), or set of memory dies.

16. The system of claim 1, wherein the RDCL scan operation is triggered periodically.

17. The system of claim 1, wherein the RDCL scan operation is triggered in response to determining that a number of read operations performed on the memory sub-system within a predetermined interval transgresses a threshold value.

18. A method comprising:
performing a read disturb induced charge loss (RDCL) scan operation on a portion of a set of memory components;
determining that a first bit error count (BEC) associated with the RDCL scan operation on the portion of the set of memory components transgresses a threshold value;
determining whether the first BEC corresponds to a second BEC that represents data retention (DR) charge loss; and
selectively refreshing data stored in the portion of the set of memory components based on determining whether the first BEC corresponds to the second BEC that represents DR charge loss.

19. The method of claim 18, wherein the set of memory components comprises a three-dimensional (3D) NAND memory.

20. A non-transitory computer-readable storage medium comprising instructions that, when executed by at least one processing device, cause the at least one processing device to perform operations comprising:
performing a read disturb induced charge loss (RDCL) scan operation on a portion of a set of memory components;
determining that a first bit error count (BEC) associated with the RDCL scan operation on the portion of the set of memory components transgresses a threshold value;
determining whether the first BEC corresponds to a second BEC that represents data retention (DR) charge loss; and
selectively refreshing data stored in the portion of the set of memory components based on determining whether the first BEC corresponds to the second BEC that represents DR charge loss.
